(19) United States
(12) Patent Application Publication
(10) Pub. No.: US 2011/0097898 A1
(43) Pub. Date: Apr. 28, 2011

(54) IMPROVED METHOD FOR DEGASSING CABLES

(75) Inventors: Jerker B.L. Kjellqvist, Waedenswil (CH); Gabriele Goethel, Merseburg (DE)

(73) Assignee: Dow Global Technologies Inc., Midland, MI (US)

(21) Appl. No.: 12/999,775

(22) PCT Filed: Jul. 1, 2009
(86) PCT No.: PCT/US09/49376

§ 371 Date: Dec. 17, 2010

Related U.S. Application Data
(60) Provisional application No. 61/077,649, filed on Jul. 2, 2008.

(51) Int. Cl. H01L 21/768

(52) U.S. Cl. 438/660; 257/E21.575

(57) ABSTRACT

The present invention is a method for degassing an electrical cable having a crosslinked, semiconductive shield layer prepared from a composition made from or containing (i) a phase I material consisting essentially of a polar copolymer of ethylene and an unsaturated ester having 4 to 20 carbon atoms, (ii) a phase II material consisting essentially of a nonpolar, low density polyethylene, and (iii) a conducting filler material dispersed in the phase I material and/or the phase II material. The de-gassing temperature is greater than 70 degrees Celsius.

The present invention relates to method of degassing an electrical cable. More specifically, the present invention relates to a method for degassing an electrical cable at a temperature higher than conventionally used.

The degassing time for high voltage cables is often the rate-limiting step in making high voltage cable. Degassing times of up to a month are common. Reducing degassing time will directly influence productivity.

It is believed that the degassing time is dictated by the amount of crosslinking byproduct gases generated as well as the rate at which the gas can diffuse out of the finished cables. The rate of diffusion is largely determined by the temperature.

Some have tried to address the degassing problem by reducing the amount of peroxide used for crosslinking the cable composition. However, this reduction has generally required the incorporation of additives that negatively affect the electrical properties of the cables. This is a significant disadvantage.

Increasing the temperature has proven to be an unacceptable route. Notably, the processing temperature for degassing cables is limited to about 60 to 70 degrees Celsius because cables tend to weld onto themselves or deform at higher temperatures.

It is desirable to increase the processing temperature for degassing cables without adversely affecting the physical characteristics of the cables. In particular, it is desirable to raise the processing temperature by at least 5 degrees Celsius above the traditional processing temperatures of 60 to 70 degrees Celsius. It is even more desirable to raise the temperature by at least 10 degrees Celsius. It is anticipated that increasing the processing temperature by 10 degrees Celsius will reduce the degassing time for some cables by as much as 30 percent.

The present invention is a method for improved degassing of a crosslinked semiconductive shield layer at a temperature greater than the conventionally-applied degassing temperature. In a first embodiment, the present method comprises the step of degassing a crosslinked semiconductive shield layer at a temperature greater than about 70 degrees Celsius. The temperature can be greater than or equal to about 75 degrees Celsius. Moreover, the temperature can be greater than or equal to about 80 degrees Celsius.

In a second embodiment, the present method comprises the step of degassing a crosslinked semiconductive shield layer at a temperature at least about 5 degrees Celsius greater than the temperature used to degas a conventional ethylene/unsaturated ester copolymer-based semiconductive shield composition.

For both described embodiments, the method uses preferentially the semiconductive shield composition described in WO/2007/092454. The composition comprises

(i) a phase I material consisting essentially of a polar copolymer of ethylene and an unsaturated ester having 4 to 20 carbon atoms;

(ii) a phase II material consisting essentially of a nonpolar, low density polyethylene; and

(iii) a conducting filler material dispersed in the phase I material and/or the phase II material in an amount sufficient to be equal to or greater than the amount required to generate a continuous conducting network in the phase I and phase II materials.

The phase I material consists essentially of a polar copolymer of ethylene and an unsaturated ester. The polar copolymers are generally made by high pressure processes. A conventional high pressure process is described in Introduction to Polymer Chemistry, Stille, Wiley and Sons, New York, 1962, pages 149 to 151. The high pressure processes are typically free radical initiated polymerizations conducted in a tubular reactor or a stirred autoclave. In the stirred autoclave, the pressure is in the range of 10,000 to 30,000 pounds per square inch (psi) and the temperature is in the range of 175 to 250 degrees Celsius, and in the tubular reactor, the pressure is in the range of 25,000 to 45,000 psi and the temperature is in the range of 200 to 350 degrees Celsius.

The unsaturated esters can be alkyl acrylates, alkyl methacrylates, and vinyl carboxylates. The alkyl group can have 1 to 8 carbon atoms and preferably has 1 to 4 carbon atoms. The carboxylate group can have 2 to 8 carbon atoms and preferably has 2 to 5 carbon atoms.

The portion of the copolymer attributed to the ester comonomer can be in the range of about 10 to about 55 percent by weight based on the weight of the copolymer, and is preferably in the range of about 15 to about 30 percent by weight. In terms of mole percent, the ester comonomer can be present in an amount of 5 to 30 mole percent. The ester can have 4 to 20 carbon atoms, and preferably has 4 to 7 carbon atoms

Examples of vinyl esters (or carboxylates) are vinyl acetate, vinyl butyrate, vinyl pivalate, vinyl neononanoate, vinyl neodecanoate, and vinyl 2-ethylhexanoate. Vinyl acetate is preferred. Examples of acrylic and methacrylic acid esters are lauryl methacrylate; myristyl methacrylate; palmityl methacrylate; stearyl methacrylate; 3-methacryloxy-propyltrimethoxysilane; 3-methacryloxypropyltriethoxysilane; cyclohexyl methacrylate; n-hexylmethacrylate; isodecyl methacrylate; 2-methoxyethyl methacrylate; tetrahydrofurfuryl methacrylate; octyl methacrylate; 2-phenoxyethyl methacrylate; isobornyl methacrylate; isooctylmethacrylate; octyl methacrylate; isooctyl methacrylate; oleyl methacrylate; ethyl acrylate; methyl acrylate; t-butyl acrylate; n-butyl acrylate; and 2-ethylhexyl acrylate. Methyl acrylate, ethyl acrylate, and n- or t-butyl acrylate are preferred. The alkyl group can be substituted with an oxyalkyltrialkoxysilane, for example.

The copolymers can have a density in the range of 0.900 to 0.990 gram per cubic centimeter, and preferably have a density in the range of 0.920 to 0.970 gram per cubic centimeter. The copolymers can also have a melt index in the range of 0.1 to 100 grams per 10 minutes, preferably have a melt index in the range of 1 to 50 grams per 10 minutes, and more preferably, in the range of 5 to 21 grams per 10 minutes.

The phase I material can be present in the composite in an amount of 10 to 80 percent by weight based on the weight of the composite, and is preferably present in an amount of 20 to 60 percent by weight.

The phase II material consists essentially of a nonpolar, low density polyethylene (LDPE) prepared as a homopolymer of ethylene and generally by a high pressure process. As previously noted, a conventional high pressure process is described in Introduction to Polymer Chemistry, Stille, Wiley and Sons, New York, 1962, pages 149 to 151. The high pressure processes are typically free radical initiated polymerizations conducted in a tubular reactor or a stirred autoclave. In the stirred autoclave, the pressure is in the range of 10,000 to 30,000 psi and the temperature is in the range of 175 to 250 degrees Celsius, and in the tubular reactor, the pressure is in the range of 25,000 to 45,000 psi and the temperature is in the range of 200 to 350 degrees Celsius.

These LDPE polymers have a density between about 0.910 grams per cubic centimeter and about 0.940 grams per cubic centimeter as measured by ASTM D-792.

The non-polar low density polyethylene preferably has a polydispersity (Mw/Mn) the range of 1.1 to 10. Mw is defined as weight average molecular weight and Mn is defined as number average molecular weight. The Mw is preferably in the range of 10,000 to 1,000,000. They also can have a melt index in the range of 0.25 to 30 grams per 10 minutes, preferably, in the range of 1 to 20 grams per 10 minutes, and more preferably, in the range of 5 to 10 grams per 10 minutes.

The phase II material can be present in the composite in an amount of 10 to 80 percent by weight based on the weight of the composite, and is preferably present in an amount of 20 to 60 percent by weight.

Optionally, additional phases of other polymeric materials can be introduced into the composite if they have properties corresponding to the properties of either the phase I material or the phase II material.

Preferably, the phase II material has a melting point greater than the melting point of the phase I material.

The polymers can be made moisture curable by making the resin hydrolyzable, which is accomplished by adding hydrolyzable groups such as —Si(OR)₃ wherein R is a hydrocarbyl radical to the resin structure through copolymerization or grafting. Suitable grafting agents are organic peroxides such as dicumyl peroxide; 2,5-dimethyl- 2,5-di(t-butylperoxy)hexane; t-butyl cumyl peroxide; and 2,5-dimethyl-2,5-di(t-butylperoxy)hexane-3. Dicumyl peroxide is preferred. Hydrolyzable groups can be added, for example, by copolymerizing ethylene with an ethylenically unsaturated compound having one or more —Si(OR)₃ groups such as vinyltrimethoxysilane, vinyltriethoxysilane, and gamma-methacryloxypropyltrimethoxy-silane or grafting these silane compounds to the resin in the presence of the aforementioned organic peroxides. The hydrolyzable resins are then crosslinked by moisture in the presence of a silanol condensation catalyst such as dibutyltin dilaurate, dioctyltin maleate, dibutyltin diacetate, stannous acetate, lead naphthenate, and zinc caprylate. Dibutyltin dilaurate is preferred.

The conducting filler material (conductive particles) can be a conventional conductive carbon black commonly used in semiconductive shields. These conductive particles have been generally provided by particulate carbon black. Useful carbon blacks can have a surface area of 50 to 1000 square meters per gram. The surface area is determined under ASTM D 4820-93a (Multipoint B.E.T. Nitrogen Adsorption). In WO/2007/092454, the carbon blacks are described as being used in the semiconductive shield composition in an amount of 10 to 50 percent by weight based on the weight of the composition, and are preferably used in an amount of 15 to 45 percent by weight, more preferably 25 to 35 percent by weight. This can be referred to as conductive filler loading, and most preferably 27 to 33 percent by weight.

While the carbon black loadings of WO/2007/092454 are useful in the present invention, the carbon black loading can be used in a lower amount than used in conventional semiconductive shield composition when applying the method of the present invention. As such and when lower carbon black loadings are desirable, the carbon black is preferably present in an amount less than 25 percent by weight; more preferably, it is present in an amount less than 15 percent by weight; and most preferably, it is present in an amount less than 10 percent by weight.

Both standard conductivity and high conductivity carbon blacks can be used with standard conductivity blacks being preferred. Examples of conductive carbon blacks are the grades described by ASTM N550, N472, N351, N110, Ketjen blacks, furnace blacks, and acetylene blacks.

Carbon black is elemental carbon in the form of spheroidal colloidal particles and coalesced particle aggregates, manufactured by the thermal decomposition of hydrocarbons. Although the carbon black has less order than graphite, carbon black microstructure is graphitic in nature. One of key characteristics of carbon black is the high degree of porosity and hollowing at the core of the carbon black particle. Carbon blacks are known as intrinsic semiconductors.

Carbon nanotubes can also be used.

Conductive fillers other than carbon black or carbon nanotubes can also be used. Examples are metallic particles, fullerenes, and conductive polymers such as polyacetylene, polyparaphenylene, polypyrrole, polythiophene, and polyaniline.

Optionally, a copolymer of acrylonitrile and butadiene wherein the acrylonitrile is present in an amount of 20 to 60 percent by weight based on the weight of the copolymer, and is preferably present in an amount of 30 to 40 percent by weight, can be included in the semiconductive shield composition. This copolymer is usually used in a strippable insulation shield rather than the conductor or strand shield. The copolymer is also known as a nitrile rubber or an acrylonitrile/butadiene copolymer rubber. The density can be, for example, 0.98 gram per cubic centimeter and the Mooney Viscosity can be (ML 1+4) 50. A silicone rubber can be substituted for the nitrile rubber, if desired.

Optionally, the composition of the present invention can contain other polyolefins, including ethylene alpha-olefin copolymers, in an amount of less than about 25 percent by weight based upon the weight of the total polymers present.

Conventional additives, which can be introduced into the composition, are exemplified by antioxidants, coupling agents, ultraviolet absorbers or stabilizers, antistatic agents, pigments, dyes, nucleating agents, reinforcing fillers or polymer additives, slip agents, plasticizers, processing aids, lubricants, viscosity control agents, tackifiers, anti-blocking agents, surfactants, extender oils, metal deactivators, voltage stabilizers, flame retardant fillers and additives, crosslinking agents, boosters, and catalysts, and smoke suppressants.

What is claimed is:

1. A method for degassing an electrical cable comprising the steps of:
(a) selecting a crosslinkable, semiconductive shield composition comprising
(i) a phase I material consisting essentially of a polar copolymer of ethylene and an unsaturated ester having 4 to 20 carbon atoms;
(ii) a phase II material consisting essentially of a nonpolar, low density polyethylene; and
(iii) a conducting filler material dispersed in the phase I material and/or the phase II material in an amount sufficient to be equal to or greater than the amount required to generate a continuous conducting network in the phase I and phase II materials;
(b) applying the crosslinkable, semiconductive shield composition over a metallic conductor to yield a semiconductive shield layer;
(c) crosslinking the semiconductive shield layer to yield an electrical cable having a crosslinked semiconductive shield layer;
(d) degassing the electrical cable at a degassing temperature greater than 70 degrees Celsius.

2. The method of claim 1 wherein the degassing temperature is greater than 75 degrees Celsius.

3. The method of claim 1 wherein the degassing temperature is greater than 80 degrees Celsius.

4. The method of any of claims 1-3 wherein the phase II material has a melting point greater than the melting point of the phase I material.
